(19) United States
(12) Patent Application Publication
(10) Pub. No.: US 2012/0199463 A1
(43) Pub. Date: Aug. 9, 2012

(54) FURNITURE ELEMENT WITH OPERATING ARRANGEMENT FOR AN ELECTRICAL DEVICE

(76) Inventor: Jürgen Heinrich, Kirchzarten (DE)

(21) Appl. No.: 13/367,575

(22) Filed: Feb. 7, 2012

(30) Foreign Application Priority Data
Feb. 9, 2011 (DE) 10 2011 010 782.7

(51) Int. Cl. H03K 17/975

(52) U.S. Cl. 200/600

(57) ABSTRACT

In a furniture element including an operating arrangement for an electrical device comprising a capacitive sensor, the furniture element is provided with a blind channel extending from one end through the furniture element into close proximity to the other end and a rod-like sensor is disposed in the blind channel for sensing movements outside the furniture piece for actuating the electrical device, the sensor being in communication with the operating arrangement for operating the electrical device depending on the movement sensed by the sensor.

### BACKGROUND OF THE INVENTION

The invention resides in a furniture element with an operating arrangement for an electrical device, in particular for a lighting device, wherein the operating arrangement includes at least one capacitive sensor disposed in the furniture element for the contact-free operation of the electrical device. The sensor is connected to an electric power supply line which supplies a voltage and/or a sensor signal output of the sensor and which is in communication with the electrical device for the control thereof. The furniture element has at the front side thereof a first surface, at the backside thereof a second surface and transverse to these surfaces, oppositely facing first and second side surfaces. The furniture element includes a channel for an electrical conductor which extends between the first surface and the second surface in spaced relationship therefrom and from the first side surface to the sensor.

Such a furniture piece is known in practice. The known furniture element includes at its backside facing away from the operating side a milled slot in which a capacitive sensor is accommodated whose detection range penetrates the furniture element so that a sensor signal of the sensor is changed when the user of the furniture element places for example his or her hand on the front side of the furniture element near the sensor. Between the front and the rear surface of the furniture element the furniture element is provided with a straight channel which extends about parallel to this surface from one end surface of the furniture element to the milled slot. In the channel, an electric line is arranged via which an electric voltage is supplied to the sensor and via which a sensed signal output is supplied to a switching device which is arranged outside the furniture element and by which the lighting device can be switched on and off. At the backside of the furniture element, the milled slot is covered by a cover which protects the sensor from contamination and from mechanical damage. In furniture elements which are also accessible from the backside such as hinged doors however the cover is disadvantageous because it is considered by the user of the furniture element to be unsightly. It is also disadvantageous because the manufacture of the furniture element involves the expense of milling a slot into the backside of the furniture element.

It is therefore the object of the present invention to provide a furniture element of the type described above which can be manufactured however at reduced cost and which pro+ vides for a visually more attractive design.

### SUMMARY OF THE INVENTION

In a furniture element including an operating arrangement for an electrical device comprising a capacitive sensor, the furniture element is provided with a blind channel extending from one end through the furniture element into close proximity to the other end and a rod-like sensor is disposed in the blind channel for sensing movements outside the furniture piece for actuating the electrical device, the sensor being in communication with the operating arrangement for operating the electrical device depending on the movement sensed by the sensor.

This arrangement makes it possible to install the sensor in a simple manner by inserting it into the blind bore. It is not necessary to mill a slot into the furniture element which detrimentally affects the appearance of, and weakens, the furniture element. The furniture element may be provided at its operating side and also at its backside with a smooth surface with no interruptions so that an optically pleasing design can be provided. Since furthermore the sensor is protected in the blind channel or bore extending through the furniture element from mechanical damage and from contamination, no cover is needed for the protection of the sensor. The contact-free actuation of the sensor can be achieved by positioning a body part such as a hand or finger near the first front side of the furniture element and/or the second and/or on another front surface of the furniture element.

In a preferred embodiment of the invention, the sensor includes a capacitive sensor element and a control and evaluation arrangement which is connected electrically to the sensor element and also to the electrical power supply wherein the control and evaluation arrangement is disposed in the blind bore between the capacitive sensor element and the electric line. The control and evaluation arrangement is then arranged in the blind bore adjacent to the sensor element whereby a high sensor signal sensitivity and a faultfree detection of a body part present in the detection range of the sensor element is facilitated.

It is advantageous if the capacitive sensor element is in the form of an elongated element which extends essentially in the longitudinal direction of the blind bore or channel. The sensor has then a high directional sensitivity in a direction transverse to the longitudinal direction of the channel and in particular at the front end of the surface at the end of the furniture element.

In a preferred embodiment of the invention, the capacitive sensor element comprises a first section and a second section wherein the first section is connected at its one end to the control and evaluation arrangement and at the remote other end to the second section of the sensor element, the first section extending essentially parallel to the longitudinal direction of the blind bore and the second section extending transverse to the first section. With the second section extending transverse to the longitudinal direction of the channel, the detection sensitivity of the sensor in the area of the second side surface area which is disposed in the extension of the blind channel is improved.

A high detection sensitivity of the sensor at the second side surface can also be achieved by providing the second section in the form of a platelet which his arranged in a plane that extends at an oblique, in particular at a right, angle with respect to the longitudinal direction of the blind channel or bore. In this case, the sensor element is preferably in the form of a bendable stamped component wherein the first and the second section of the sensor element are interconnected.

It is advantageous if the second section is in the form of an open or closed ring which is an integral part of the first section. The second section in this case can also be in the form of a curved wire which extends in a plane which is arranged transverse to, and in particular normal, to the longitudinal direction of the blind bore. Also, with this arrangement, a simple antenna is provided which provides for high directional sensitivity of the sensor in the axial direction of the blind bore.

Preferably, the capacitive sensor includes an electrically insulating hose in which the sensor element and the control and evaluation arrangement are disposed. The sensor element is then protected in the hose from contamination. The hose, is preferably a shrink hose. It may be sealingly closed at its end in order to protect the sensor element and the control and evaluation arrangement from moisture and other environmental influences.

In another advantageous embodiment of the invention, the capacitive sensor includes an essentially form-stable tubular housing in which the sensor element and the control and evaluation arrangement are disposed. Also in this housing, the sensor element and the control and evaluation element can be protected from contamination and moisture. By this housing, the sensor element and the control evaluation arrangement are furthermore protected during installation from contact and from mechanical damages. In addition, the housing may eliminate any stresses on the electrical cable.

In a preferred embodiment of the invention, the housing includes a first tubular housing part and a second tubular housing part wherein these tubular housing parts are telescopically joined and are adjustable between a retracted and an expanded position in the first housing part, the control and evaluation arrangement is disposed and in the second housing part at least part of the sensor element is arranged, the sensor element being mechanically coupled to the second housing part at a location which is axially spaced from the control and evaluation arrangement and wherein a section of the sensor element which is disposed between this location and the control and evaluation arrangement consists of a bendable material whose cross-section is smaller than the open cross-section of the second housing part. In this way, the effective length of the sensor element can be changed in a simple manner by telescoping the housing parts in or out for changing the detection characteristics of the sensor element. With the housing parts moved into one another the sensor detects mainly in axial direction whereas, with the housing parts extended the sensor is also sensitive in a direction transverse to the axial direction. In this way, the same sensor can be used for different installation conditions:
Actuation exclusively for point-like finger operation,
Actuation for point-like finger operation and aerial operation,
Actuation exclusively aerial operation.

In the last case, the sensor is so positioned during installation in the blind bore that the distance from the second front side area is so large that a body part positioned there cannot activate the operating function. It is also mentioned that in the retracted position a section of the housing part may be arranged between the control and evaluation element and the first housing part. In this way, a compact sensor element can be provided.

If desirable, the actuating arrangement may include at least two of the capacitive sensors arranged in the furniture part, wherein these sensors are in control communication with the electric arrangement via a control logic and wherein the control logic is so designed that the electrical arrangement is operable depending on the actuating sequence and/or the actuating duration of the sensors. In this way, it is in particular possible to detect the direction of movement of a body part over the sensor for actuating the sensor so that different functions are initiated depending on the direction of the movement, as for example the switching on or off of different lamps or the up or down dimming of at least one lighting device.

The invention will become more readily apparent from the following description of particular embodiments thereof with reference to the accompanying drawings.

### BRIEF DESCRIPTION OF THE DRAWINGS

FIG. 1 shows a first furniture element with an operating arrangement for an electrical illumination device,

FIG. 2 shows a block diagram of the operating arrangement and the illumination device,

FIG. 3 is a side view of a first exemplary embodiment of a capacitive sensor,

FIGS. 4-7 show various capacitive sensor elements,

FIG. 8 is a side view of a second embodiment of a capacitive sensor,

FIG. 9 shows a second embodiment of a furniture element with an operating arrangement for an electrical illumination arrangement, and

FIG. 10 is a cross-sectional view of a furniture element.

### DESCRIPTION OF PARTICULAR EMBODIMENTS

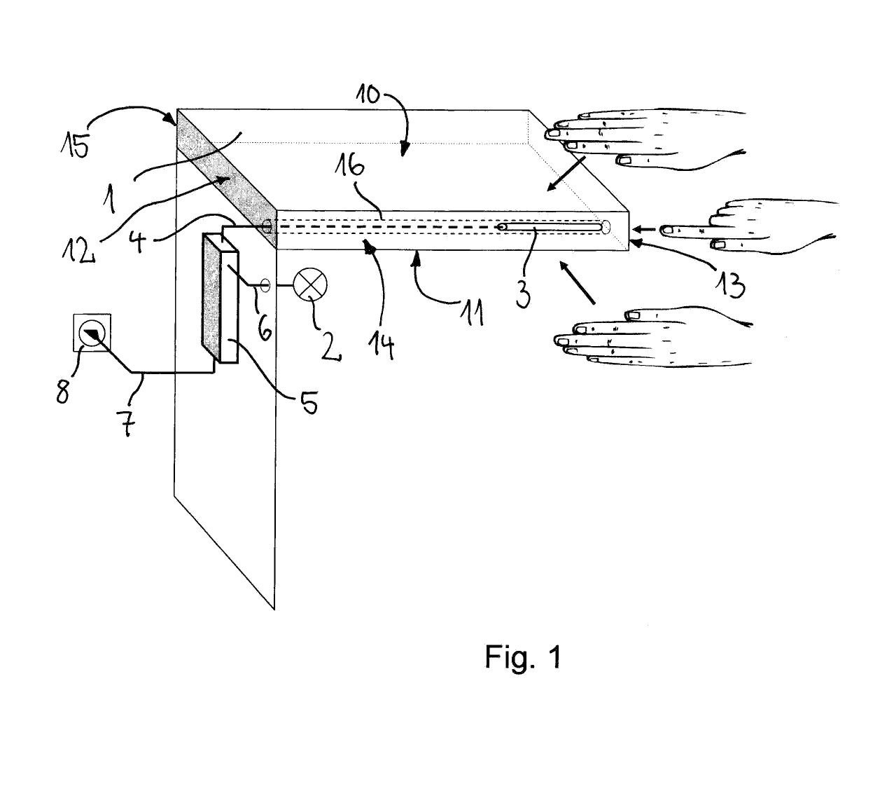

As shown in FIG. 1, a furniture element 1 is provided with an illumination arrangement including a lighting means 2 which can be activated by an operating arrangement in a contact-free manner.

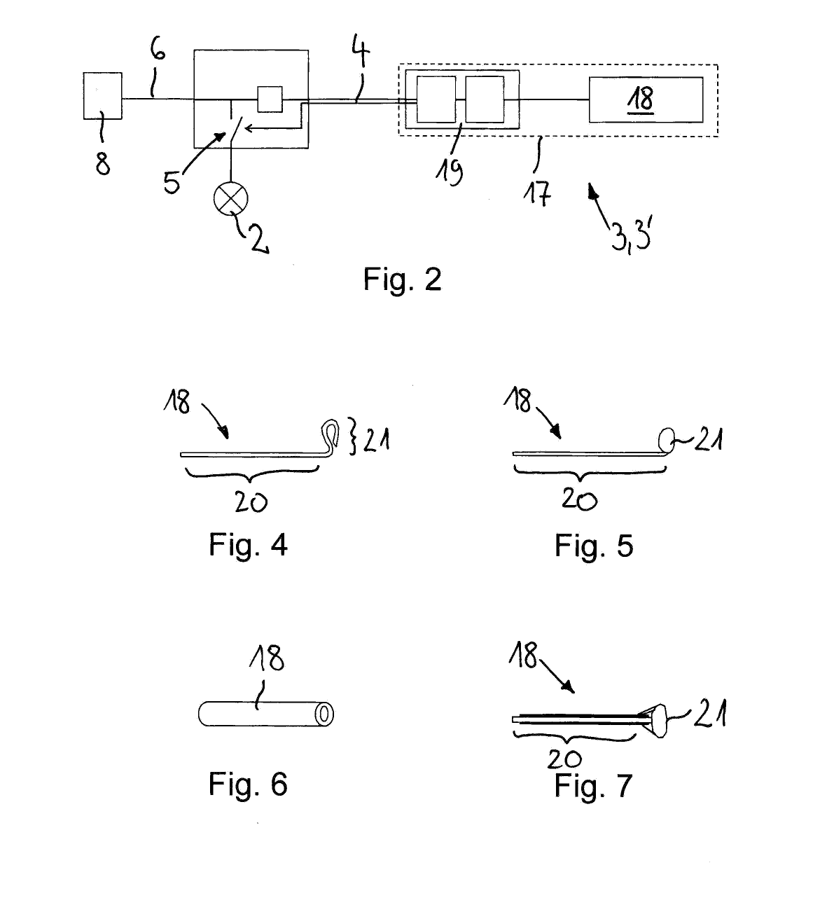

The operating arrangement comprises a capacitive sensor 3 which is incorporated in the material of the furniture element 1 and which is connected to an electric power supply line 4 that supplies low-voltage power for the sensor and for the transmission of a sensor signal to a switching device 5. As shown in FIG. 2, the lighting means 2 can be connected by means of the switching device 5 to a power supply system. The switching device 5 is connected to the lighting device 2 via a first cable 6 and, via a second cable 7, to a power outlet 8 of the power supply.

The furniture element 1 is a plate-like single part component and has, at its front end facing a user when in a use position, a first surface 10 and at the opposite back side a second surface 11. The furniture element 1 has further a first end surface 12 and a second end surface 13 which are disposed opposite each other and face away from each other and which extend transverse to the first and second surfaces 10 and 11. A third side surface 14 and a fourth side surface 15 extend transverse to the surfaces 10, 11 and transverse to the end surfaces 12 and 13.

In the material of the furniture element which may consist for example of wood, plastic, stone or glass a channel 16 for accommodating the electrical line 4 is provided. The channel 16 extends between the first surface 10 and the second surface 11 but is spaced from these surfaces. The channel 16 is also spaced from the third surface 14 and the fourth surface 15.

As shown in FIG. 1, the channel 16 is in the form of a blind bore which extends from the first end surface 12 toward the second end surface 13 and ends ahead of the second end surface 13 at a distance therefrom of about four millimeters. Between the channel 16 and the surfaces 10, 11 and also the third side surface 14 there is also a distance of only a few millimeters.

The channel 16 extends along a straight line and has a circular cross-section. The channel 16 can be formed into the first end surface 12 of the furniture element 1 by means of a corresponding drill.

The sensor 3 is a rod-like elongated component which is arranged at the inner end of the channel 16 adjacent the second end surface 13. To facilitate insertion of the sensor 3 during assembly axially into the channel 16 the cross-sectional dimensions of the sensor 3 are somewhat smaller than the cross-sectional dimensions of the channel 16.

The power supply line 4 enters in the sensor 3 at its end remote from the inner end of the passage 16. At the point of entry, a connecting means is provided via which any tension forces applied to the power supply line 4 are taken up by the housing 17 of the sensor but which means are not shown in the drawing. The housing 17 is essentially tubular.

If necessary the housing 17 may be filled by a casting material.

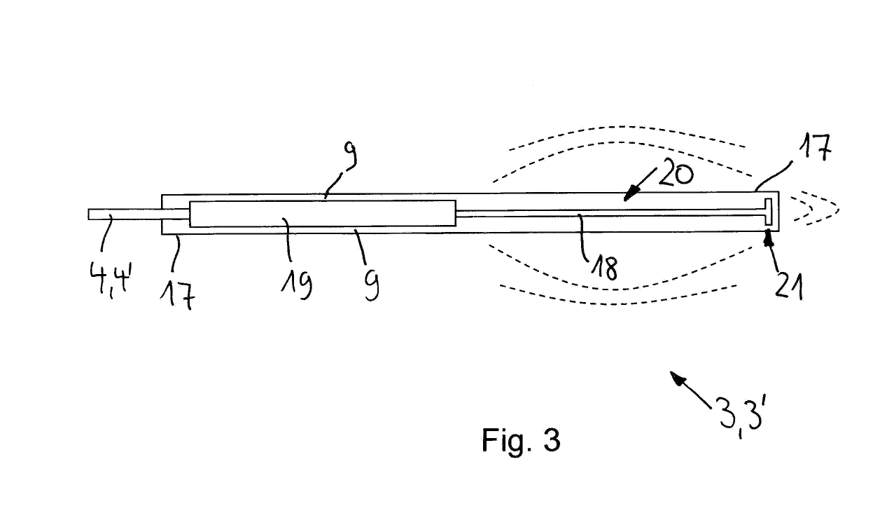

From FIG. 2, it is apparent that the sensor 3 includes in the housing 17 an antenna-like capacitive sensor element 18 and a control and evaluation arrangement 19 electrically connected to the sensor element 18. The sensor element 18 consists of an electrically conductive material for example of metal or an electrically conductive plastic material. By means of the control and evaluation arrangement 19, a high10 frequency electromagnetic signal can be applied to the sensor element 18. The electromagnetic signal which in FIG. 3 is indicated schematically in the form of dashed field lines penetrates the material of the furniture element 1 and extends up to a space which is adjacent the channel 16 outside the furniture element 1.

The sensor element 18 is connected to the electric power supply line 4 via the control and evaluation arrangement 19. The sensor element 18 is an elongated element which extends essentially in the longitudinal direction of the channel 16.

By means of the control and evaluation arrangement 19, the capacitive current which depends on the permeability of the surroundings and which flows via the sensor element to the ground and back to the control and evaluations arrangement 19 can be measured. The control and evaluation arrangement 19 includes a comparator which is not shown in the drawing by means of which the measured current can be compared with a reference value. Depending on the comparison result obtained in this way the control and evaluation arrangement 19 generates a digital detection signal which controls the switching device 5 by way of the line 4.

As shown in FIGS. 4, 5 and 7, the sensor element 18 includes a first section 20 and a second section 21. The first section 20 is connected at its one end to the control and evaluation arrangement 19 and at its opposite end to the sensor section 21. The first section extends essentially parallel to the longitudinal direction of the channel 16 and the second section 21 extends in a plane which extends transverse, and in particular at a right angle to, the longitudinal direction of the channel 16. The second section 21 can be bent to an annular shape (FIG. 4) or it may be a flat platelet (FIG. 5). In FIG. 6, it is shown that the sensor element may also be in the form of a tube.

As shown in FIG. 1, the illumination device may be operated by a body part as for example a hand or a finger approaching the first surface 10, the second front surface 13 and/or the third side surface 14.

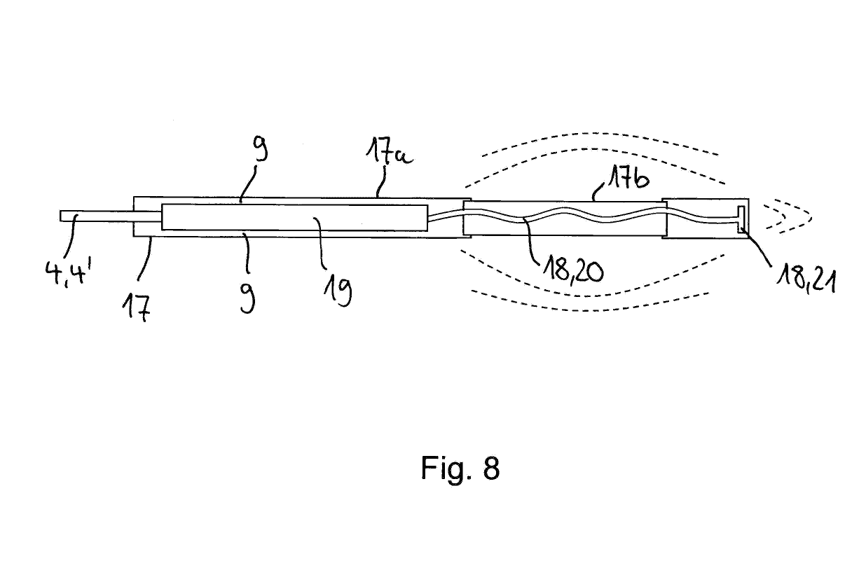

In the exemplary embodiment of the sensor 2 as shown in FIG. 18, the housing includes a first tubular housing part 17a and a second tubular housing part 19b which are joined telescopically and which are movable between a retracted position and an extended position as shown in FIG. 8. In the first housing part 17a, the Control and evaluation arrangement 19 is disposed. Between the control and evaluation arrangement 19 and the internal wall of the first housing part 17a, there is an intermediate space 9 in which the second housing part 17b is accommodated when the housing parts are in the retracted state.

In the second housing part 17b, a flexible partial area of the sensor element 18 is arranged. The sensor element 18 is at its one end fixed to the control and evaluation arrangement 19 and at its other end to the second housing part 17b. From FIG. 8, it is also apparent that the outer diameter of the flexible part of the sensor element 18 is substantially smaller than the inner diameter of the second housing part 17b so that the effective length of the sensor element 18 is shortened when the housing parts 17a, 17b are moved together. Correspondingly, the effective length of the sensor element 18 is extended when the housing parts 17a, 17b are moved apart. As a result, upon installation of the sensor 3, the length of the sensor element 18 can be adjusted by moving the housing parts 17a, 17b relative to one another.

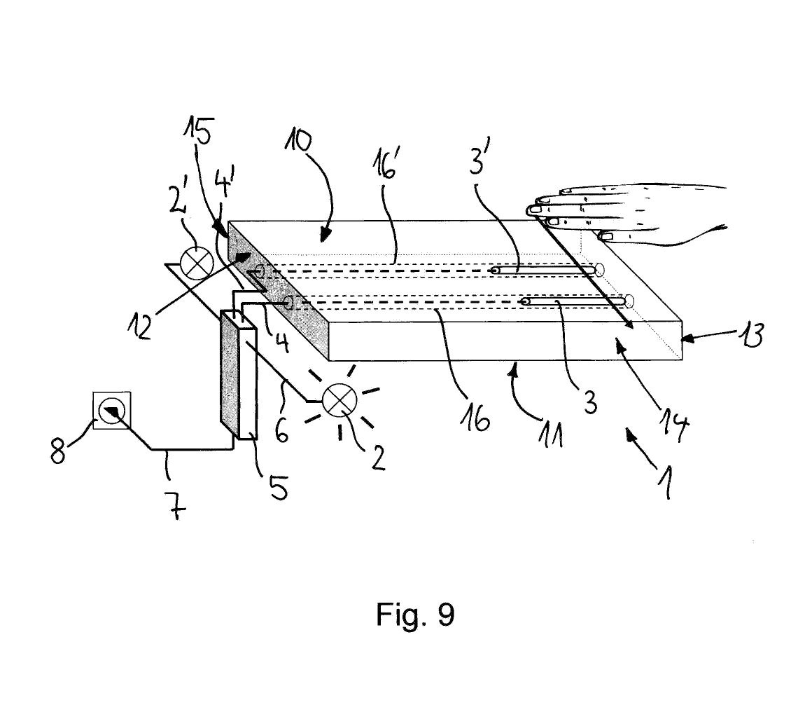

In the exemplary embodiment shown in FIG. 9, the operating arrangement includes two capacitive sensors 3, 3′ arranged in the furniture element and two separately switchable lighting means 2, 2′. The sensors 3, 3′ are in control communication with the lighting means 2, 2′ via a control logic in such a way that the electrical arrangement is adjustable depending on the operating sequence and/or the operating duration of the sensors 3, 3′. The control logic detects the time-shifted movement over the first sensor and the second sensor 3′ and determines therefrom the movement direction and the movement speed. With the first movement direction, a first lighting means 2 is activated and with the second movement direction a second lighting means 2′ is activated, for example switched on or switched off. With a continuous movement both lighting means 2, 2′ are deactivated. With rapid back and forth movement activated lighting means are dimmed.

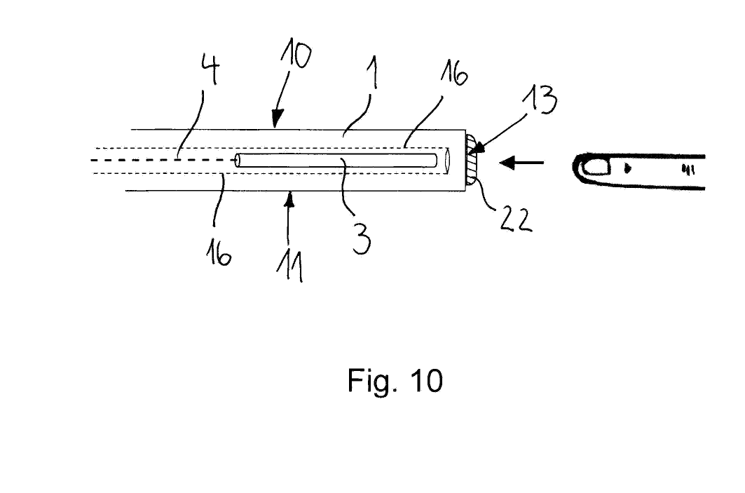

It is finally mentioned that, for easily finding the operating position of the capacitive sensor 3, 3′, an adhesive platelet 22 or an adhesive label may be applied to the front end surface 13 (FIG. 10). The adhesive platelet 22 may consist of plastic or of metal. It is preferably so designed that it can be easily removed without a stain from the front end surface 13 when the user is familiar with the operating location.

Reference List

| | |
|---|---|
| 1 | Furniture element |
| 2 | Lighting means |
| 2′ | Lighting means |
| 3 | Capacitive sensor |
| 3′ | Capacitive sensor |
| 4 | Electric line |
| 5 | Switching device |
| 6 | First cable |
| 7 | Second cable |
| 8 | Power supply socket |
| 9 | Intermediate space |
| 10 | First surface |
| 11 | Second surface |
| 12 | First end side surface |
| 13 | Second end side surface |
| 14 | Third end side surface |
| 15 | Fourth end side surface |
| 16 | Channel |
| 16′ | Channel |
| 17 | Housing |
| 17a | First housing part |
| 17b | Second housing part |
| 18 | Capacitive sensor element |
| 19 | Control and evaluation arrangement |
| 20 | First section |
| 21 | Second section |
| 22 | Adhesive platelet |

What is claimed is:

1. A furniture element (1) with an operating arrangement for an electrical device, in particular for a lighting arrangement, including in the furniture element (1) a capacitive sensor (3, 3′), an electric line (4, 4′) connected to the sensor (3, 3′) for supplying electric energy to the sensor or the supply of a sensor signal from the sensor (3, 3′) to an electrical device which is in control-communication with the sensor, the furniture element (1) having a front side with a first surface (10), a backside with a second surface (11) and first and second end surfaces (12, 13) which extend transverse to the first and second front and back surfaces (10, 11) and which are arranged opposite, and face away from, each other, the furniture element (1) having further a channel (16, 16′) extending between the front surface (10) and the back surface 911) in spaced relationship therefrom and from the first end surface (12) in the form of a blind channel (16, 16′) in close proximity to the second end surface (13), the sensor (3, 3′) being an elongated rod-like device disposed in the channel (16, 16′) and having a cross-section with dimensions smaller than those of the channel (16, 16′).

2. The furniture element according to claim 1, wherein the sensor (3, 3′) comprises a capacitive sensor element (18) and includes a control and an evaluation arrangement (19) electrically connected to the sensor element (18) and to the electric line (4, 4′), the control and evaluation arrangement (19) being arranged in the channel (16, 16′) between the capacitive sensor element (18) and the electrical line (4, 4′).

3. The furniture element according to claim 1, wherein the capacitive sensor element (3, 18) is in the form of an elongate body which extends essentially in the longitudinal direction of the channel (16, 16′).

4. The furniture element according to claim 3, wherein the capacitive sensor element (18) comprises a first section (20) and a second section (21) and the first section (20) is connected at one end thereof to the control and evaluation arrangement (19) and the second section (21) of the sensor element (18) is disposed at its opposite end, the first section (20) extending essentially parallel to the longitudinal direction of the channel (16) and the second section (21) extending in a direction transverse to the first section (20).

5. The furniture element according to claim 4, wherein the second section (2) is in the form of a platelet disposed in a plane transverse to the longitudinal direction of the channel (16).

6. The furniture element according to claim 4, wherein the second section (21) is in the form of an open or closed ring which is formed integrally with the first section (20).

7. The furniture element according to claim 2, wherein the capacitive sensor (3, 3′) comprises an electrically insulating hose in which the sensor element (18) and the control and evaluation arrangement (19) are arranged.

8. The furniture element according to claim 2, wherein the capacitive sensor (3, 3′) comprises an essentially formstable housing (17) in which the sensor element (18) and the control and evaluation arrangement (19) are arranged.

9. The furniture element according to claim 8, wherein the housing comprises at least a first tubular housing part (17a) and a second tubular housing part (17b) and the housing parts are joined telescopically and movable between a retracted position and an extended position wherein, in the first housing part (17a), the control and evaluation arrangement is disposed and in the second housing part (17b) at least part of the sensor element (18) is disposed and wherein the sensor element (18) is mechanically connected to the second housing part (17b) at a location which is axially spaced from the control and evaluation arrangement (19) and, in a section of the sensor element (18) between this location and the control evaluation arrangement (19), consists of a flexible material whose cross-section is smaller than the cross-section of the second housing part (17b).

10. The furniture element according to claim 1, wherein the operating arrangement includes at least two capacitive sensors (3, 3′) arranged in the furniture element (1) and these sensors (3, 3′) are in communication via a control logic with an electric control unit (5), the control logic being designed so as to actuate the control unit (3) depending on a movement sequence or direction sensed by the sensors (3, 3′).
